(19) United States
(12) Patent Application Publication
(10) Pub. No.: US 2015/0031165 A1
(43) Pub. Date: Jan. 29, 2015

(54) PHOTOVOLTAIC DEVICE INTERCONNECT

(71) Applicant: First Solar, Inc., Perrysburg, OH (US)

(72) Inventors: Oleh P. Karpenko, Richmond, CA (US); Jianjun Wang, Perrysburg, OH (US)

(21) Appl. No.: 14/483,537

(22) Filed: Sep. 11, 2014

Related U.S. Application Data
(62) Division of application No. 13/220,061, filed on Aug. 29, 2011.
(60) Provisional application No. 61/378,259, filed on Aug. 30, 2010.

(51) Int. Cl. H01L 31/18; H01L 31/0224

(52) U.S. Cl. CPC H01L 31/1832; H01L 31/022466; H01L 31/022475
USPC 438/95

(57) ABSTRACT

Scribing and deposition processes can be used to interconnect cells within photovoltaic modules.

### CLAIM OF PRIORITY

This application is a divisional of U.S. patent application Ser. No. 13/220,061, filed Aug. 29, 2011, which claims priority under 35 U.S.C. §119(e) to Provisional Application No. 61/378,259, filed on Aug. 30, 2010, which are hereby incorporated by reference in their entireties.

### TECHNICAL FIELD

The present invention generally relates to interconnections between photovoltaic cells in photovoltaic modules.

### BACKGROUND

A photovoltaic module can include a plurality of photovoltaic cells connected in a series-parallel configuration. Adjacent cells are electrically connected using interconnects. During usage, current densities within the interconnects can be high. As a result of these high current densities, existing modules experience power losses stemming from contact resistances between interconnects and the front contact layer. Moreover, existing methods for forming interconnects can result in contamination of a semiconductor layer resulting in poor adhesion of a back contact layer to the semiconductor layer. Poor adhesion may result in reduced performance and reliability.

### DESCRIPTION OF DRAWINGS

FIG. 1 is a partially assembled photovoltaic module including a plurality of photovoltaic cells on a substrate.

FIG. 2 is cross-sectional view of a portion of a multilayer structure.

FIG. 3 is a cross-sectional perspective view of a portion of a partially assembled photovoltaic module following a first scribing process.

FIG. 4 is a cross-sectional perspective view of a portion of a partially assembled photovoltaic module following a cell isolation process.

FIG. 5 is a cross-sectional perspective view of a portion of a partially assembled photovoltaic module following a second scribing process.

FIG. 6 is a cross-sectional perspective view of a portion of a partially assembled photovoltaic module following a second deposition process.

FIG. 7 is a cross-sectional perspective view of a portion of a partially assembled photovoltaic module following removal of a sacrificial layer.

FIG. 8 is a cross-sectional perspective view of a portion of a partially assembled photovoltaic module following formation of a back contact layer.

FIG. 9 is a cross-sectional perspective view of a first embodiment of a portion of the partially assembled photovoltaic module of FIG. 1 taken along section A-A.

FIG. 10 is a cross-sectional perspective view of a second embodiment of a portion of the partially assembled photovoltaic module of FIG. 1 taken along section A-A.

### DETAILED DESCRIPTION

Photovoltaic modules can include multiple layers (or coatings) created on a substrate (or superstrate). For example, a photovoltaic device or cell can include a barrier layer, a transparent conductive oxide (TCO) layer, a buffer layer, and a semiconductor layer formed in a stack on a substrate. Each layer may in turn include more than one layer or film. For example, the semiconductor layer can include a first film including a semiconductor window layer, such as a cadmium sulfide layer, formed on the buffer layer and a second film including a semiconductor absorber layer, such as a cadmium telluride layer formed on the semiconductor window layer. Additionally, each layer can cover all or a portion of the device and/or all or a portion of the layer or substrate underlying the layer. For example, a “layer” can include any amount of any material that contacts all or a portion of a surface.

Photovoltaic module performance can be improved by using a first material for the interconnect and using a second material for the back contact layer. By introducing a sacrificial layer that protects a semiconductor layer, an interconnect may be formed without contaminating the semiconductor layer. Once the interconnect has been formed, the sacrificial layer can be removed and replaced with a back contact layer. This approach allows unique materials to be used for the interconnect and the back contact layer. In particular, a material having a work function matching the front contact layer can be used for the interconnect, and a material that adheres favorably to the semiconductor layer can be used for the back contact layer.

In known modules, the interconnect material and back contact layer are formed through a single deposition step. As a result, the interconnect and back contact layer contain the same material. This is undesirable since the interconnect and back contact layer serve different purposes within the module and are exposed to different conditions. For example, due to its small cross-sectional area, the interconnect may experience very high current densities. Unfortunately, the known approach does not permit for customization of the interconnect material independent of the back contact material. As a result, a single material must be selected that is suitable for both but optimal for neither.

In one aspect, a method for manufacturing a photovoltaic module may include forming a transparent conductive oxide layer adjacent to a substrate layer, forming a first semiconductor layer adjacent to the transparent conductive oxide layer, forming a second semiconductor layer adjacent to the first semiconductor layer, and forming a sacrificial layer adjacent to the second semiconductor layer. The method may include scribing a first trench extending from the sacrificial layer to the substrate layer. The method may include depositing an insulating material in the first trench, where the insulating material extends from the substrate layer beyond the transparent conductive oxide layer. The method may include scribing a second trench extending from the sacrificial layer to the transparent conductive oxide layer. The method may include depositing a first conductive material in the second trench, wherein the first conductive material extends from the transparent conductive oxide layer toward the sacrificial layer. The method may include removing the sacrificial layer thereby exposing the second semiconductor layer. The method may include forming a back contact layer adjacent to the second semiconductor layer, where the back contact layer comprises a second conductive material. The method may include scribing a third trench extending from the back contact layer to the second semiconductor layer. The method may include removing the sacrificial layer to expose the second semiconductor layer. The method may include forming a lower conductive layer adjacent to the second semiconductor layer, where the lower conductive layer comprises a second conductive material. The method may include forming an upper conductive layer adjacent to the lower conductive layer, where the upper conductive layer fills the second trench and comprises a first conductive material.

With respect to the method described above, the sacrificial layer may include a material selected from the group consisting of aluminum, zinc, cadmium, or cadmium oxide. The transparent conductive oxide layer may include a material selected from the group consisting of tin oxide, cadmium stannate, or any other suitable material. The first semiconductor layer may include cadmium sulfide. The second semiconductor may include a material selected from the group consisting of cadmium telluride or copper indium gallium (di)selenide. The first conductive material may include a material selected from the group consisting of molybdenum nitride, copper, aluminum, or chromium. The second conductive material may include a material selected from a group consisting of molybdenum nitride, copper, aluminum, or chromium.

In another aspect, a multilayer structure may include a transparent conductive oxide layer adjacent to a substrate layer, a first semiconductor layer adjacent to the transparent conductive oxide layer, a second semiconductor layer adjacent to the first semiconductor layer, and a sacrificial layer adjacent to the second semiconductor layer.

In another aspect a photovoltaic module may include a transparent conductive oxide layer adjacent to a substrate layer, a first semiconductor layer adjacent to the transparent conductive oxide layer, a second semiconductor layer adjacent to the first semiconductor layer, a back contact layer adjacent to the second semiconductor layer, and a trench extending from the transparent conductive oxide layer to the back contact layer. The trench may be filled with a first conductive material, and the back contact layer may include a second conductive material.

In another aspect, a photovoltaic module may include a transparent conductive oxide layer adjacent to a substrate layer, a first semiconductor layer adjacent to the transparent conductive oxide layer, a second semiconductor layer adjacent to the first semiconductor layer, a lower conductive layer adjacent to the second semiconductor layer, an upper conductive layer adjacent to the lower conductive layer, and a trench extending from the transparent conductive oxide layer to the upper conductive layer. The upper conductive layer may include a first conductive material, and the lower conductive layer may include a second conductive material. The trench may be filled with the first conductive material.

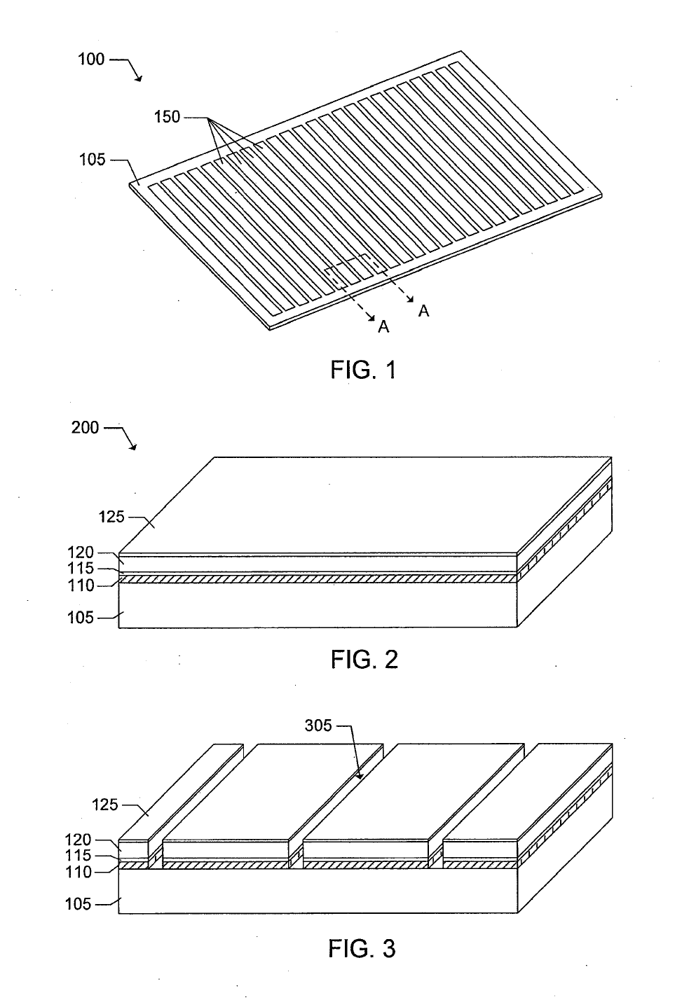

As shown in FIG. 1, a partially assembled photovoltaic module 100 may include a plurality of photovoltaic cells 150 formed adjacent to a substrate layer 105. The substrate layer 105 may be formed from an optically transparent material such as soda-lime glass or float glass having low iron content to improve transmission. The plurality of cells 150 may be formed through a combination of scribing and deposition steps as described below.

By way of example, FIG. 2 shows a cross-sectional view of a portion of a multilayer structure 200. Through a combination of scribing and deposition steps, the multilayer structure can be converted into a plurality of photovoltaic cells 150 as shown in FIG. 1. The multilayer structure 200 may include a transparent conductive oxide (TCO) layer 110 formed adjacent to the glass substrate 105. The TCO layer 110 may serve as a front contact for the plurality of cells 150. When selecting a material for the TCO layer 110, it is desirable to select a material that is highly conductive and highly transparent. The TCO layer 110 may include, for example, tin oxide, cadmium stannate, or indium tin oxide. If cadmium stannate is selected, application may be accomplished by mixing cadmium oxide with tin dioxide using a 2:1 ratio and depositing the mixture onto the substrate 105 using radio frequency magnetron sputtering or vapor deposition.

A first semiconductor layer 115 may be formed adjacent to the TCO layer 110. The first semiconductor layer 115 may be a n-type window layer and may include a thin layer of cadmium sulfide. For instance, the first semiconductor layer 115 may be about 0.1 microns thick. The first semiconductor layer 115 may be deposited using any suitable thin-film deposition technique such as, for example, sputtering or vapor deposition.

A second semiconductor layer 120 may be formed adjacent to the first semiconductor layer 115 and may serve as a p-type absorber layer. The second semiconductor layer 120 may include any suitable material including, for example, cadmium telluride or copper indium gallium (di)selenide. The second semiconductor layer 120 may be deposited using any suitable thin-film deposition technique such as, for example, sputtering or vapor deposition.

A sacrificial layer 125 may be formed adjacent to the second semiconductor layer 120. The sacrificial layer may protect the second semiconductor layer from contamination resulting from a cell isolation process described below. The sacrificial layer may include low metals having low electronegativity or dielectric material. For example, the sacrificial layer may include any suitable material such as, for example, aluminum, zinc, cadmium, cadmium oxide, tellurium oxide, or cadmium telluride.

Adjacent cells in the module can be electrically connected via electrical interconnects. Interconnects can be formed through a combination of scribing and deposition steps, where scribing involves material removal and deposition involves material addition. Scribing may include laser scribing with, for example, pulsed lasers. Deposition may be accomplished using any suitable deposition technique such as physical vapor deposition, chemical vapor deposition, electrochemical deposition, reactive vapor deposition, or liquid polymer injection. Physical vapor deposition may include sputtering or evaporation, and chemical vapor deposition may include plasma enhanced chemical vapor deposition or atomic layer deposition.

To convert the multilayer structure 200 into a plurality of cells 150, a three-scribe process may be used. As shown in FIG. 3, the first scribing process may penetrate the sacrificial layer 125, the semiconductor layers (115, 120) and the TCO layer 110 to form a first trench 305. By removing the TCO layer 110 between a first cell 905 and a second cell 910, the first scribing process serves to electrically isolate a front contact 915 of a first cell 905 from a front contact 920 of a second cell 910, as shown in FIG. 9.

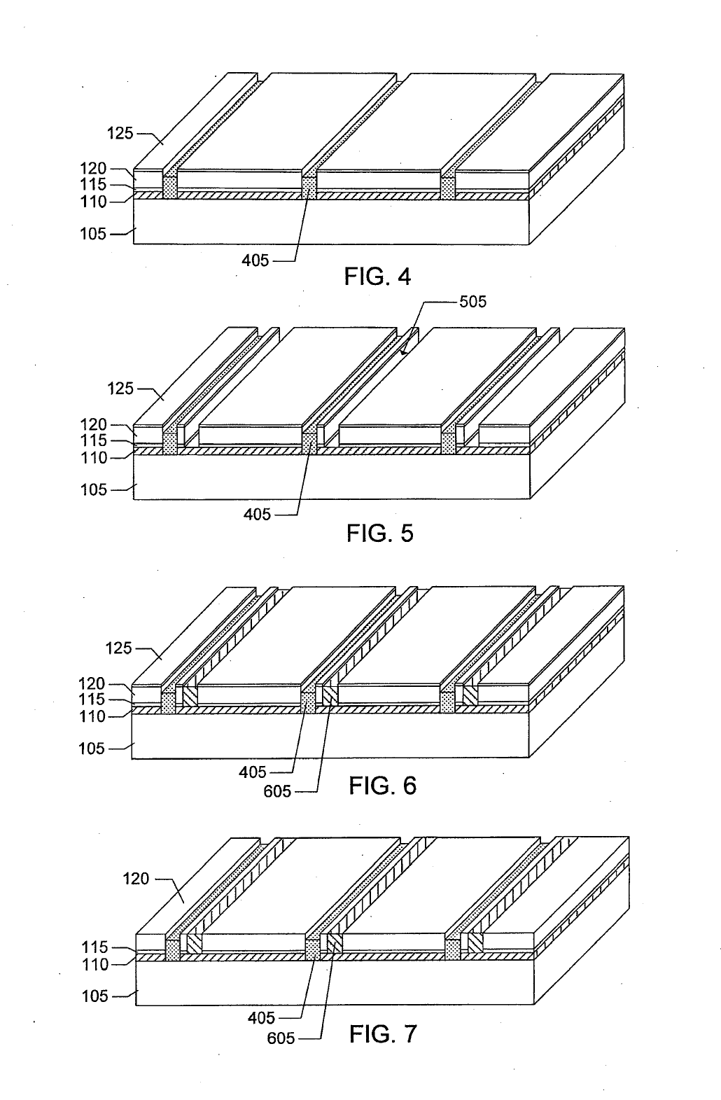

The first trench 305 may be filled with an insulating material 405 during a cell isolation process as shown by way of example in FIG. 4. The insulating material 405 provides electrical insulation between the front contact 915 of the first cell 905 and the front contact 920 of the second cell 910. As a result, the insulating material 405 reduces leakage current and improves module efficiency. The insulating material 405 can be deposited in the first trench 305 using any suitable process. The insulating material may include any suitable material such as, for example, photoresist or dielectric material. Examples of suitable dielectric materials include silicon oxide, silicon nitride, and silicon carbide. If photoresist is used, it may be deposited in the first trench 305 and cured through exposure to ultraviolet light. If dielectric material is used, it may be deposited in the first trench 305 by plasma enhanced chemical vapor deposition, atomic layer deposition, reactive vapor deposition, or any other suitable process.

The sacrificial layer 125 protects the second semiconductor layer 120 from being contaminated with insulating material 405 during the deposition process. The insulating material 405 may extend from the substrate layer 105 to a position at or below the sacrificial layer 125. For example, the insulating material 405 may extend from the substrate 105 to the first semiconductor layer 115. Alternately, the insulating material 405 may extend from the substrate 105 to the second semiconductor layer 120. So long as the insulating material 405 extends beyond the TCO layer 110, any depth is appropriate.

As shown in FIG. 5, a second scribing process may penetrate the sacrificial layer 125 and the semiconductor layers (115, 120) to form a second trench 505. A deposition process may fill the second trench 505 with a first conductive material 605 as shown in FIG. 6. The first conductive material 605 can extend from the TCO layer 110 to the sacrificial layer 125. By doing so, an interconnect 935 is formed that provides a series connection between a back contact layer 925 of the first cell 905 and the front contact 920 of the second cell 910.

Several series connections are depicted by arrows in FIGS. 9 and 10, where the arrows represent current pathways through the interconnects. Since the interconnect 935 may experience current densities ranging from about 1 A/cm2 to about 10 A/cm2, it is important to minimize contact resistances to limit power losses. In particular, it is desirable to minimize the contact resistance between the interconnect 935 and the TCO layer 920. This can be accomplished by selecting a conductive material having a work function matching the work function of the TCO layer 920. For example, the first conductive material may include molybdenum nitride, copper, aluminum, chromium.

The sacrificial layer 125 protects the second semiconductor layer 120 from contamination during the formation of the interconnect 935, and thereby prevents photoresist residue from forming or residing on the second semiconductor layer 120. Photoresist residue is undesirable because it reduces cell efficiency and promotes delamination of a back contact layer 805 from the second semiconductor layer 120. Once the first and second trenches (505, 605) have been filled with material, the sacrificial layer 125 is no longer required and can be removed as shown in FIG. 7. Removal may be accomplished by any suitable method such as, for example, wet chemical etching with phosphoric acid.

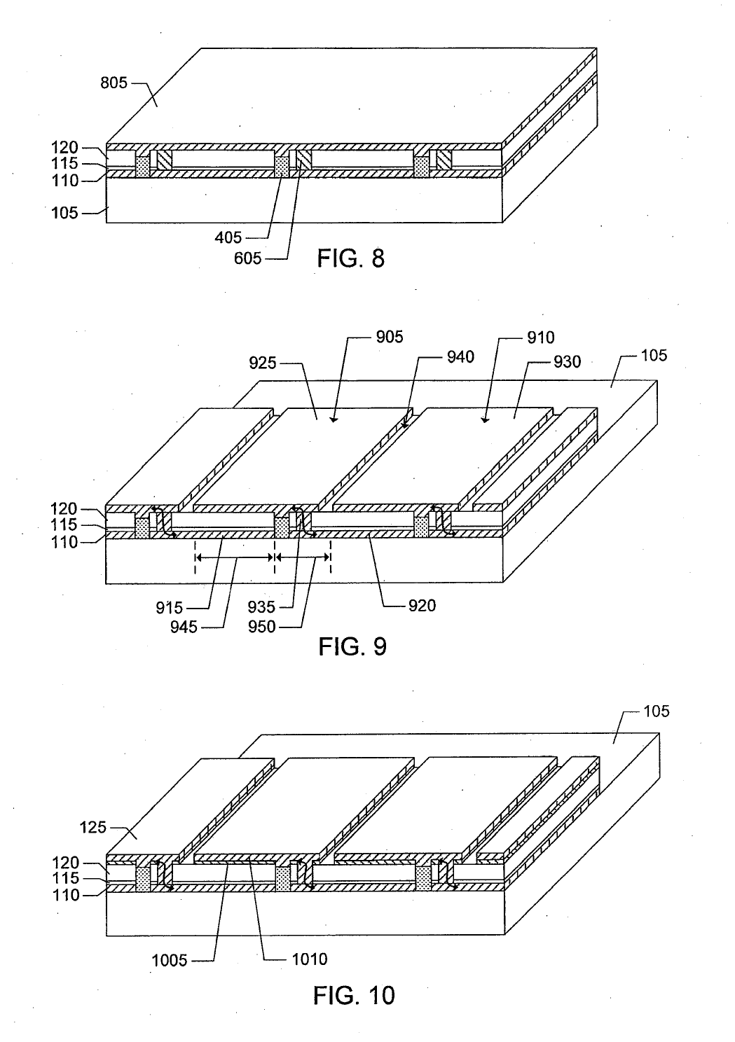

Once the sacrificial layer 125 has been removed, the back contact layer 805 can be formed adjacent to the second semiconductor layer 120 through a metallization process, as shown in FIG. 8. The back contact layer 805 may extend to the insulating material 405 in the first trench 305 and the first conductive material 605 in the second trench 505. It is desirable to have a strong adhesion between the back contact layer 805 and the second semiconductor material 120 to ensure module reliability. Strong adhesion also promotes improved performance resulting from a solid electrical connection between the mating surfaces. Adhesion is controlled in part by the cleanliness of the interface, which is maintained through introduction and removal of the sacrificial layer 125. Adhesion is also controlled by the material properties of the back contact layer 805. Therefore, it is important that the material selected for the back contact material 805 mate well with the second semiconductor layer 120. The back contact layer 805 may include a second conductive material, and the second conductive material can include any suitable material including, for example, molybdenum nitride, copper, aluminum, chromium.

Once the back contact layer 805 has been formed, a third scribing process may be used to divide the back contact layer 805 into a plurality of back contact layers (e.g. 925, 930), as shown in FIG. 9. The third scribing process may penetrate the back contact layer 805 to form a third trench 940. The third trench 940 may extend to the second semiconductor layer 120, thereby isolating the back contact layer 925 of the first cell 905 from the back contact layer 930 of the second cell 910. To further isolate adjacent cells, an insulating material can be added to the third trench 940. For example, a polymer interlayer may be added as described below.

The scribing and deposition steps described above create active areas 945 and dead areas 950 within the module as shown in FIGS. 9 and 10. Active areas 945 produce photo-generated current, whereas dead areas 950 do not. Therefore, to improve conversion efficiency of the module, it is desirable to minimize the sized of dead areas 950. Dead area size can be reduced by decreasing the width of the trenches (305, 505, 940), which can be accomplished by using a narrow laser beam diameter. The dead area can also be reduced by grouping the first, second, and third trenches (305, 505, 940) closer together.

FIG. 10 shows an alternate embodiment for photovoltaic cell interconnection. Formation of the alternate embodiment follows a process similar to that shown and described in FIGS. 1-5. However, the process differs from FIG. 5 onward. In particular, the next step is removal of the sacrificial layer 125. Then, a lower conductive layer 1005 may be formed adjacent to the second semiconductor layer 120. The lower conductive layer 1005 may include a first conductive material as described above. An upper conductive layer 1010 may then be formed adjacent to the lower conductive layer 1005 and may fill the second trench 505 as shown in FIG. 10. The upper conductive layer 1010 may include a second conductive material as described above.

Once the plurality of cells 110 have been formed, one or more protective layers may be formed adjacent to the cells. For example, a polymer interlayer may be formed adjacent to the back contact layer, and a cover plate may be formed adjacent to the polymer interlayer 135. The polymer interlayer 135 may include, for example, ethylene-vinyl acetate (EVA), and the protective back substrate 140 may include, for example, soda-lime glass, fiberglass, plastic, carbon fiber, or rubber.

Photovoltaic modules may be more sophisticated or less sophisticated than those shown. For example, a more sophisticated module may include additional layers thereby providing enhanced performance or reliability. The figures are provided as an example of a photovoltaic module and, accordingly, are not limiting. Further, the apparatus and methods disclosed herein may be applied to any type of photovoltaic technology including, for example, cadmium telluride, cadmium selenide, amorphous silicon, organic, and copper indium gallium (di)selenide (CIGS). Several of these photovoltaic technologies are discussed in U.S. patent application Ser. No. 12/572,172, filed on Oct. 1, 2009, which is incorporated by reference in its entirety.

Details of one or more embodiments are set forth in the accompanying drawings and description. Other features, objects, and advantages will be apparent from the description, drawings, and claims. Although a number of embodiments of the invention have been described, it will be understood that various modifications may be made without departing from the spirit and scope of the invention. Also, it should also be understood that the appended drawings are not necessarily to scale, presenting a somewhat simplified representation of various features and basic principles of the invention.

What is claimed is:

1. A method for manufacturing a photovoltaic module, the method comprising:
forming a transparent conductive oxide material over a substrate;
forming a first semiconductor material over the transparent conductive oxide material;
forming a second semiconductor material over the first semiconductor material;
forming a removable sacrificial material in contact with the second semiconductor material;
creating a plurality of individual photovoltaic cell structures by forming trenches through one or more of the transparent conductive oxide material and first and second semiconductor materials, and filling the trenches with a respective material; and removing the sacrificial material after creation of the cell structures to expose the second semiconductor layer.

2. The method of claim 1, wherein the sacrificial material comprises a material selected from the group consisting of aluminum, zinc, cadmium, cadmium oxide, tellurium oxide, and cadmium telluride.

3. The method of claim 1, wherein the transparent conductive oxide material comprises a material selected from the group consisting of tin oxide and cadmium stannate.

4. The method of claim 1, wherein the first semiconductor material comprises cadmium sulfide.

5. The method of claim 1, wherein the second semiconductor material comprises a material selected from the group consisting of cadmium telluride and copper indium gallium (di)selenide.

6. The method as in claim 1, wherein the creation of the individual photovoltaic cell structures comprises forming a first set of trenches through the sacrificial material, transparent conductive oxide material, and the first and second semiconductor materials and filling the first set of trenches with an insulating material.

7. The method as in claim 6, wherein the first set of trenches is formed by a scribe process.

8. The method as in claim 6, wherein the creation of the individual photovoltaic cell structures further comprises forming a second set of trenches down to the transparent conductive oxide material through the sacrificial material and first and second semiconductor materials.

9. The method as in claim 8, wherein the creation of the individual photovoltaic cells further comprises filling the second set of trenches with a first conductive material.

10. The method as in claim 6, wherein the insulating material in the first set of trenches extends from the substrate beyond the transparent conductive oxide material.

11. The method as in claim 2, wherein the first set of trenches extend to the substrate.

12. The method of claim 9, wherein the first conductive material extends from the transparent conductive oxide layer toward the sacrificial layer.

13. The method of claim 9, further comprising: forming a back contact material over the exposed second semiconductor material and in contact with the first conductive material, wherein the back contract layer material comprises a second conductive material.

14. The method of claim 13, further comprising: forming a third trench extending from the back contact material to the second semiconductor material.

15. The method of claim 8, further comprising: filling the second set of trenches with a first conductive material after the sacrificial material is removed.

16. The method of claim 15, wherein the filling of the second set of trenches comprises forming an upper conductive material over the second semiconductor material, wherein the upper conductive material fills the second set of trenches to form the first conductive material.

17. The method as in claim 13, wherein the back contact material and first conductive material are different conductive materials.

18. The method of claim 9, wherein the first conductive material comprises a material selected from the group consisting of molybdenum nitride, copper, aluminum, and chromium.

19. The method of claim 13, wherein the second conductive material comprises a material selected from a group consisting of molybdenum nitride, copper, aluminum, and chromium.
